(19) United States
(12) Patent Application Publication
(10) Pub. No.: US 2009/0116183 A1
(43) Pub. Date: May 7, 2009

(54) Gas Assisted Thixotropic Molded Chassis For Cooling A Computer Chassis

(75) Inventor: Kevin Mundt, Austin, TX (US)

Correspondence Address: HAYNES AND BOONE, LLP;IP Section, 2323 Victory Avenue, Suite 700, Dallas, TX, 75219, US

(73) Assignee: DELL PRODUCTS L.P., Round Rock, TX (US)

(21) Appl. No.: 11/933,671

(22) Filed: Nov. 1, 2007

(51) Int. Cl. G06F 1/20; B22D 18/00; F28D 15/00; H05K 7/20

(52) U.S. Cl. 361/679.46; 164/119; 165/104.28; 164/76.1

(57) ABSTRACT

A housing including a housing portion having a reinforcing rib including a cylindrical cross-section. The rib provides reinforcing for the housing and may simultaneously provide a cooling passage for the housing. A cooling path is defined through the housing by the cylindrical cross-section of the rib.

### BACKGROUND

The present disclosure relates generally to information handling systems, and more particularly to providing cooling channels and/or structural members in the chassis of an information handling system.

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Many present notebook computers are liquid cooled via a heat pipe. The heat pipe moves the heat from a hot component such as a central processing unit (CPU) to a radiator near the edge of the system. The heat pipe has a length limitation that causes component layout issues in some larger foot print form factors. In addition there is a desire to more evenly distribute a system's heat load through more of the system's surfaces. Most notebook or portable computer users are familiar with “hot” spots on the bottom surface of the notebook. Spreading the heat more evenly across the entire surface allows the heat density to be divided by the incremental increase in surface area. A method of accomplishing this is to create fluid channels through the entire dissipation surface and pump fluid through the channels to move the heat from the hot areas to cooler areas. Adding fluid channels to a surface generally requires adding tubing or adding a plate to create fluid paths. Both of these solutions increase system thickness and system weight.

Metal-based notebook computers are generally made from molded magnesium. The molding processes are either die-casting or thixotropic molding. The thixotropic molding process is similar to the injection molding process that is used to manufacture plastic parts. Both injection processes inject the molten/melted material (magnesium or plastic) into a mold that has a cavity the shape of the final part.

An additional process for plastic injection molding is gas assist injection molding. A common problem with injection-molded parts is a depression in the cosmetic surface called a “sink”. A sink can be caused in an area of the part that has a reinforcing rib on the opposite surface of the part. The area that has internal features such as the rib has a thicker wall section and therefore has more plastic mass. The increased mass cools at a slower rate than the rest of the part. The slower cooling rate causes this area of the part to shrink more than the common wall thickness. Such shrinking causes a cosmetic depression on the surface of the part. Gas assist was developed as a method to eliminate this type of cosmetic blemish. Gas assist molding injects a nitrogen gas charge into the molten injection molded plastic part. The skin of the plastic part chills instantly upon plastic injection. The nitrogen gas charge migrates to the thick sections of the plastic part, and because the surface has already chilled, the gas bubble equalizes at the center of the thick sections. When accomplished correctly in a plastic part, all of the wall sections attain equal thickness and the cosmetic sink is eliminated.

Thixotropic magnesium molding has less of an issue with cosmetic sink than plastic injection molding. Therefore, the gas assist molding process has not been taken to the thixotropic molding process. A common result of gas assist injection when used in molded plastic parts as described above, is a continuous internal passage within the plastic part. If a rib is run in a particular path through the plastic part, the gas assist injection will provide a continuous tube or passage internal to the part in a path that follows the rib. This internal passage has potential to be a fluid path for cooling purposes, however, plastic parts do not meet the structural needs of commercial notebooks. Plastic is also a poor thermal transfer medium. However, such an internal path in a metal part would be useful for cooling.

Accordingly, it would be desirable to provide an information handling system having a chassis base formed by injection molded metal to provide internal cooling passages to be integrated within the wall of the molded metal part in the form of a tubular reinforcing rib. The tubular structure that is created by the gas assist void is structurally more rigid than a taller rib without the void. The lower height of the new structure allows for other system components to occupy the space above the rib.

### SUMMARY

In this disclosure, gas assisted channels within the magnesium parts are utilized to move a fluid within the walls of the metal part with minimal weight and size increase to the base part. Magnesium has adequate thermal transfer properties to conduct heat from the thermal transfer fluid to the exterior surfaces of the notebook where the heat can be dissipated to the surrounding air. This provides the ability to create cooling channels within the magnesium wall of the notebook computer's base chassis part.

According to one embodiment, a housing comprises a housing member which includes a reinforcing rib having a cylindrical cross-section. The rib provides reinforcing for the housing and may simultaneously provide a cooling passage for the housing.

### BRIEF DESCRIPTION OF THE DRAWINGS

FIG. 1 is a block diagram illustrating an embodiment of an information handling system (IHS).

FIG. 2 is a perspective view illustrating an embodiment of a portable IHS.

FIG. 3 is a diagrammatical top down view illustrating an embodiment of a portable IHS chassis with the keyboard removed.

FIG. 4 is a cross-sectional view taken along the line 4-4 of FIG. 3.

FIG. 5 is an enlarged cross-sectional view extracted from FIG. 4 as indicated.

### DETAILED DESCRIPTION

For purposes of this disclosure, an IHS may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a network server or storage device, a switch router or other network communication device, or any other suitable device and may vary in size, shape, performance, functionality, and price. The IHS may include memory, one or more processing resources such as a central processing unit (CPU) or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communications between the various hardware components.

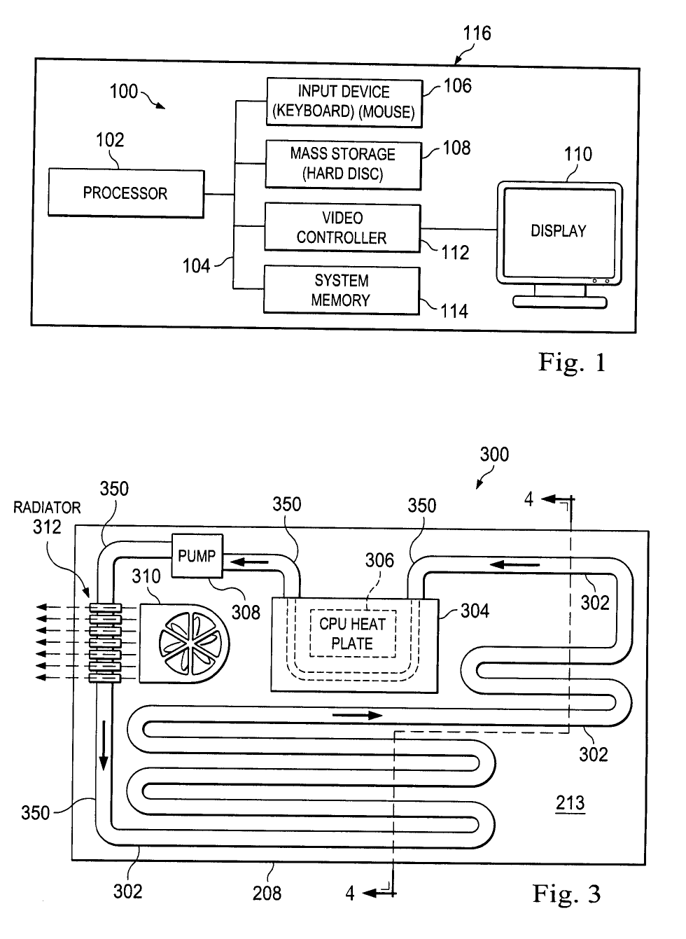

In one embodiment, IHS 100, FIG. 1, which may be a portable laptop or notebook computer includes a processor 102, which is connected to a bus 104. Bus 104 serves as a connection between processor 102 and other components of computer system 100. An input device 106 is coupled to processor 102 to provide input to processor 102. Examples of input devices include keyboards, touchscreens, and pointing devices such as mouses, trackballs and trackpads. Programs and data are stored on a mass storage device 108, which is coupled to processor 102. Mass storage devices include such devices as hard disks, optical disks, magneto-optical drives, floppy drives and the like. IHS 100 further includes a display 110, which is coupled to processor 102 by a video controller 112. A system memory 114 is coupled to processor 102 to provide the processor with fast storage to facilitate execution of computer programs by processor 102. In an embodiment, a chassis or housing 116 houses some or all of the components of IHS 100. It should be understood that other buses and intermediate circuits can be deployed between the components described above and processor 102 to facilitate interconnection between the components and the processor 102.

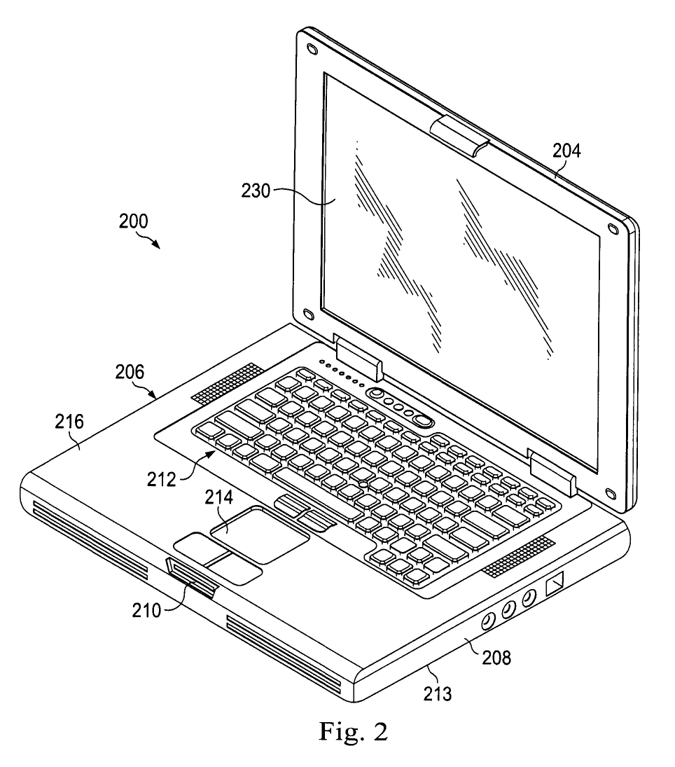

In FIG. 2, a portable laptop or notebook computer 200 is shown, further illustrating an embodiment of IHS 100 of FIG. 1. The portable computer 200 comprises a chassis 202 having a top portion 204 and a bottom portion 206. The bottom portion 202 includes a majority of the computer components, not shown, some of which are heat producing components. The top portion 204, shown in an open position, is pivotably connected to the bottom portion 206 and includes a display 230. Bottom portion 206 generally comprises a metal housing portion 208, where many of the components are stored, covered by a cover plate 216 and also includes a latch 210 to secure top portion 204 when pivoted to a closed position. Cover plate 216 includes a keyboard 212 and a mousepad 214. Inasmuch as the bottom portion 206 includes heat producing components, cooling is required for proper operation and user comfort. Such cooling is provided by means located in a bottom surface 213 of housing portion 208.

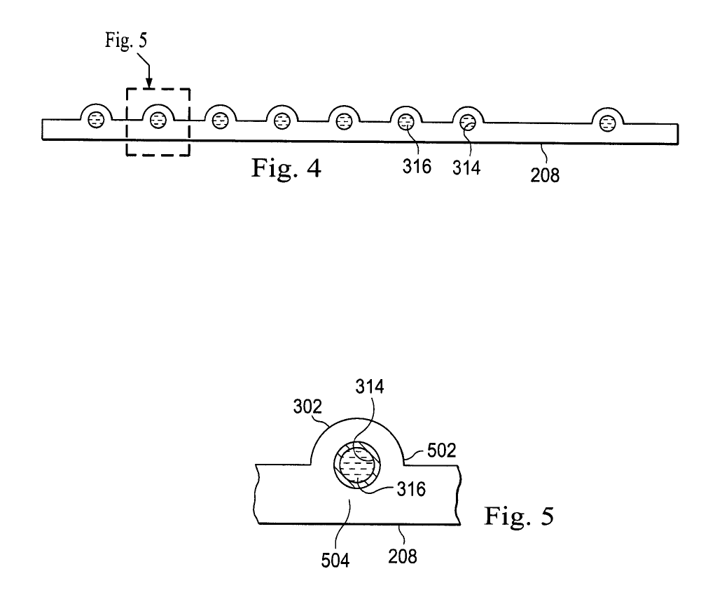

In FIG. 3, cover plate 216 of FIG. 2 is removed to reveal a top-down view of the bottom surface 213 of housing portion 208. Also, many of the above-mentioned components are not shown. In FIG. 4, a cross-sectional view of the bottom surface 213 is illustrated.

Therefore, in FIGS. 3 and 4, an elongated reinforcing rib pattern 300, which is of a serpentine shape in this embodiment, is illustrated. The rib pattern 300 includes an elongated rib 302 extending along the bottom surface 213 coupled to a heat sink or heat plate 304 which accommodates a heat generating processor 306. A pump 308 is coupled to rib 302 as is a fan 310 and a radiator 312. An elongated passage 314 extends through rib 302.

Passage 314 is a closed loop system and carries a suitable cooling fluid 316, similar to a heat pipe. The fluid 316 is moved through plate 304 and radiator 312 by pump 308. Fan 310 functions to pass air over radiator 312 to cool the fluid 316 which has been heated due to the processor 306 generating heat onto plate 304.

It can be seen from the foregoing that rib 302, including passage 314 provide a dual purpose member in housing 208. The rib 302 is a reinforcing member which strengthens bottom surface 213 of housing 208. The rib 302 also includes passage 314 which carries the cooling fluid 316.

The housing 208 which includes the unique dual purpose rib 302 including the coolant passage 314, is formed in a novel manner in that the gas assist molding process has not been used with the thixotropic molding process. This is because the thixotropic magnesium molding has less of an issue with cosmetic sink that plastic injection molding, which commonly is used with a gas assist.

After injection of the thixotropic magnesium, cooling begins at an outside edge 502, FIG. 5. The gas assist molding process injects a nitrogen gas charge into the housing portion 208. The outside edge or skin 502 chills almost instantly after injection of the magnesium and the nitrogen gas migrates to a thick region 504 of housing portion 208. Because the skin 502 has chilled, the gas bubble equalizes at the center of the thick region 504 where the thixotropic magnesium is not chilled, and permits the unchilled material to be expelled from the housing portion 208 along the thickened rib 302, thus forming the elongated passageway 314.

When assembling the device as illustrated in FIG. 3, flexible coupling conduit members 350 can be used to couple the elongated rib 302 and the passageway 314 to the heat plate 304, the pump 308 and the radiator 312.

Thus, resulting reinforcing rib 302 has a tubular or cylindrical cross-section which is structurally stronger than the typical rectangular cross-section of such housing ribs, and due to the lower height of the cylindrical rib, the housing provides more space for system components to occupy the space above the rib 302. Furthermore, the passage 314, formed in the rib 302, can be used to carry a coolant for reducing the housing temperature resulting from the heat producing components.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

1. A housing comprising:
a housing member including a dual purpose member comprising:
means for reinforcing the housing; and
means for cooling the housing.

2. The housing of claim 1, further comprising:
the housing member being formed by an injection molded, heated thixotropic metal slurry.

3. The housing of claim 2, further comprising:
the means for reinforcing including an elongated reinforcing rib being molded into the housing member by the slurry.

4. The housing of claim 3, further comprising:
the means for cooling including a cooling passage being formed along the length of the rib.

5. The housing of claim 4, wherein the cooling passage is formed by forcing a gas into the rib as the slurry cools.

6. The housing of claim 5, wherein the cooling passage extends in a serpentine path along the housing member.

7. An information handling system comprising:
a housing;
a processor mounted in the housing;
a memory coupled to the processor for executing instructions provided by the processor; and
a portion of the housing including a dual purpose member comprising:
means for reinforcing the housing; and
means for cooling the housing.

8. The system of claim 7, further comprising:
the portion of the housing being formed by an injection molded, heated thixotropic metal slurry.

9. The system of claim 8, wherein the dual purpose member comprises an elongated reinforcing rib molded into the housing portion by the slurry.

10. The system of claim 9, wherein the dual purpose member comprises a cooling passage being formed along the length of the rib.

11. The system of claim 10, wherein the cooling passage is formed by forcing a gas into the rib as the slurry cools.

12. The system of claim 11, wherein the cooling passage extends in a serpentine path.

13. A method of providing a cooling device comprising;
forming a metal part for housing a device to be cooled:
the metal part including an elongated structural reinforcing member having a cooling passage; and
the metal part formed by an injected thixotropic hot slurry and by a gas forced into the reinforcing member to form an elongated cooling passage therein.

14. The method of claim 13, further comprising:
integrating the metal part into a housing.

15. The method of claim 14, further comprising:
filling the passage with a cooling fluid.

16. The method of claim 15, further comprising:
mounting a heat producing component in the housing.

17. The method of claim 16, further comprising:
coupling the passage to a pump for moving the fluid.

18. The method of claim 17, further comprising:
coupling the passage to the heat producing component.

19. The method of claim 18, further comprising:
coupling the passage to a heat extracting component.

20. The method of claim 19, further comprising:
extending the passage in a serpentine path along the metal part.

21. A housing comprising:
a housing member including an elongated reinforcing rib; and
the housing member and the rib being formed by an injected thixotropic hot slurry and by a gas forced into the rib to form an elongated passage therein,
wherein the rib has a cylindrical cross-section.

22. A housing comprising:
a housing member including an elongated rib; and
the housing member and the rib being formed by an injected thixotropic hot slurry and by a gas forced into the rib to form an elongated passage therein,
wherein the rib has a cylindrical cross-section for carrying a coolant in the passage.
